(19) United States
(12) Patent Application Publication
(10) Pub. No.: US 2023/0225111 A1
(43) Pub. Date: Jul. 13, 2023

(54) SEMICONDUCTOR MEMORY DEVICES AND METHODS FOR FABRICATING THE SAME

(71) Applicant: Samsung Electronics Co., Ltd., Suwon-si (KR)

(72) Inventors: Dong Hwan Lee, Daejeon (KR); Hyuck Jin Kang, Seoul (KR); Chan Woo Shin, Seoul (KR); Min Wu Kim, Hwaseong-si (KR); Jung Woo Song, Hwaseong-si (KR)

(21) Appl. No.: 17/936,552

(22) Filed: Sep. 29, 2022

(30) Foreign Application Priority Data
Jan. 7, 2022 (KR) 10-2022-0002792

(51) Int. Cl. H01L 27/108; G11C 5/06

(52) U.S. Cl. CPC H01L 27/10814; G11C 5/063; H01L 27/10823; H01L 27/10897

(57) ABSTRACT

A semiconductor device and a related fabrication method are provided. The semiconductor device includes a conductive line on a substrate, a capping pattern that extends along an upper surface of the conductive line, a spacer structure that extends along a side surface of the conductive line and a side surface of the capping pattern, a buried contact electrically connected to the substrate, on a side surface of the spacer structure, a barrier conductive film extending along the buried contact and the spacer structure, and a landing pad electrically connected to the buried contact, on the barrier conductive film and the capping pattern, wherein an upper part of the spacer structure includes a spacer recess that is lower than or equal to an uppermost surface of the capping pattern, and the barrier conductive film extends along the spacer recess and does not cover the uppermost surface of the capping pattern.

### CROSS-REFERENCE TO RELATED APPLICATION

This application claims priority from Korean Patent Application No. 10-2022-0002792 filed on Jan. 7, 2022, in the Korean Intellectual Property Office and all the benefits accruing therefrom under 35 U.S.C. 119, the contents of which in its entirety are herein incorporated by reference.

### BACKGROUND

The present disclosure relates to semiconductor memory devices. As semiconductor memory devices have become more highly integrated, individual circuit patterns have further miniaturized to implement more semiconductor memory devices in the same area. However, the miniaturization of individual circuit patterns can increase the degree of process difficulty and can cause defects.

For example, in a semiconductor memory device including a capacitor, a landing pad may be used to electrically connect the capacitor and the bit line. As an interval between adjacent landing pads gradually decreases, bad connections, such as an interconnection between the adjacent landing pads or disconnection of each landing pad, may occur.

### SUMMARY

Aspects of the present inventive concept provide a semiconductor memory device having improved reliability.

Aspects of the present inventive concept also provide a method for fabricating a semiconductor memory device having improved reliability.

However, aspects of the present inventive concept are not restricted to those set forth above. The above and other aspects of the present inventive concept will become more apparent to one of ordinary skill in the art to which the present inventive concept pertains by referencing the detailed description of the present inventive concept given below.

According to aspects of the present inventive concept, there is provided a semiconductor memory device comprising a substrate, a first conductive line on the substrate, a capping pattern that extends along an upper surface of the first conductive line, a spacer structure that extends along a side surface of the first conductive line and a side surface of the capping pattern, a buried contact electrically connected to the substrate, on a side surface of the spacer structure, a barrier conductive film extending along the buried contact and the spacer structure, and a landing pad electrically connected to the buried contact, on the barrier conductive film and the capping pattern, wherein an upper part of the spacer structure includes a spacer recess that is lower than or equal to an uppermost surface of the capping pattern, and the barrier conductive film extends along the spacer recess and does not cover the uppermost surface of the capping pattern.

According to aspects of the present inventive concept, there is provided a semiconductor memory device comprising a substrate, a first conductive line on the substrate, a capping pattern that extends along an upper surface of the first conductive line, a spacer structure that includes a first side spacer and a second side spacer that are stacked sequentially on a side surface of the first conductive line and a side surface of the capping pattern, the first side spacer and the second side spacer including different materials from each other, a buried contact electrically connected to the substrate on a side surface of the spacer structure, a first barrier conductive film extending along the buried contact and the spacer structure, and a landing pad electrically connected to the buried contact, on the first barrier conductive film and the capping pattern, wherein an upper part of the spacer structure includes a spacer recess that is lower than or equal to an uppermost surface of the capping pattern, the first barrier conductive film extends along the spacer recess and is in contact with an upper part of the first side spacer and an upper part of the second side spacer, and the landing pad includes a lower pad on the side surface of the capping pattern and the side surface of the spacer structure, and an upper pad that is in contact with an uppermost surface of the first barrier conductive film and the uppermost surface of the capping pattern, on the lower pad.

According to aspects of the present inventive concept, there is provided a semiconductor memory device comprising a substrate including an active region, a bit line extending in a first direction on the substrate, a direct contact that electrically connects the active region and the bit line, a first capping pattern that extends along an upper surface of the bit line, a spacer structure that extends along a side surface of the bit line and a side surface of the first capping pattern, a buried contact electrically connected to the active region, on a side surface of the spacer structure, a barrier conductive film extending along the buried contact and the spacer structure, a landing pad electrically connected to the buried contact, on the barrier conductive film and the first capping pattern, a capacitor structure that is electrically connected to the landing pad, on the landing pad, and a word line that extends in a second direction intersecting the first direction, and crosses the active region between the direct contact and the buried contact, wherein an upper part of the spacer structure includes a curved region that is lower than or equal to an uppermost surface of the first capping pattern, and the barrier conductive film extends along the curved region of the spacer structure and does not cover the uppermost surface of the first capping pattern.

According to aspects of the present inventive concept, there is provided a method for fabricating a semiconductor memory device, the method comprising forming a first conductive line and a capping pattern extending along an upper surface of the first conductive line, on a substrate, forming a spacer structure extending along a side surface of the first conductive line and a side surface of the capping pattern, forming a buried contact electrically connected to the substrate, on a side surface of the spacer structure, performing a recess process on the spacer structure to form a spacer recess in an upper part of the spacer structure, forming a preliminary barrier conductive film on the buried contact, the spacer structure and the capping pattern, forming a first conductive film electrically connected to the buried contact, on the preliminary barrier conductive film, performing a planarization process on the preliminary barrier conductive film and the first conductive film to form a barrier conductive film and a lower pad that do not cover an upper surface of the capping pattern, forming a second conductive film on the lower pad, the barrier conductive film, and the capping pattern, and patterning the second conductive film to form an upper pad connected to the lower pad.

### BRIEF DESCRIPTION OF THE DRAWINGS

The above and other aspects and features of the present inventive concept will become more apparent by describing in detail example embodiments thereof with reference to the attached drawings, in which:

FIG. 1 is an example layout diagram for explaining the semiconductor memory device according to some embodiments.

FIG. 2 is a partial layout diagram for explaining a cell region and the core/peripheral (peri) region of FIG. 1.

FIG. 3 is a cross-sectional view taken along lines A1-A1 and A2-A2 of FIG. 2.

FIGS. 4A to 4F are various enlarged views for explaining a region S of FIG. 3. FIG. 5 is a cross-sectional view taken along a line B-B of FIG. 2. FIG. 6 is a cross-sectional view taken along a line C-C of FIG. 2. FIG. 7 is a cross-sectional view taken along a line D-D of FIG. 2.

FIGS. 8 to 23 are intermediate step diagrams for explaining a method for fabricating a semiconductor memory device according to some embodiments.

### DETAILED DESCRIPTION

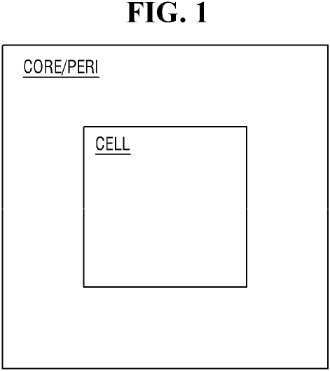

Hereinafter, a semiconductor memory device according to example embodiments will be described referring to FIGS. 1 to 7.

Although terms such as a first and a second are used to describe various elements or components in the present specification, these elements or components are not limited by these terms. These terms are merely used to distinguish a single element or component from other elements or components. Therefore, a first element or component referred to below may be a second element or component without departing from the scope of the present inventive concept.

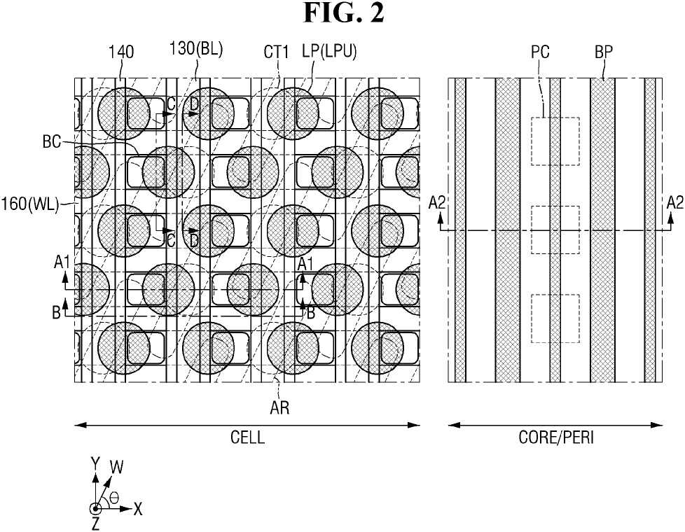

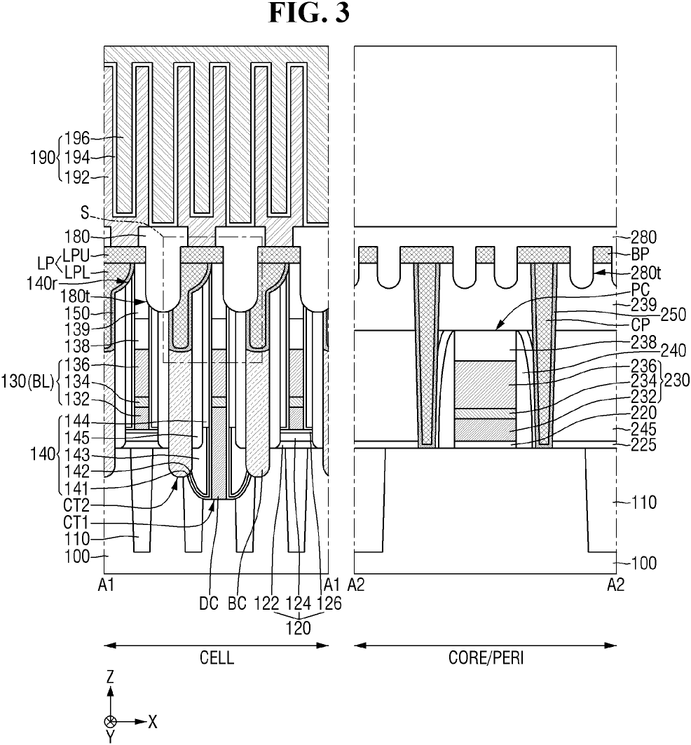

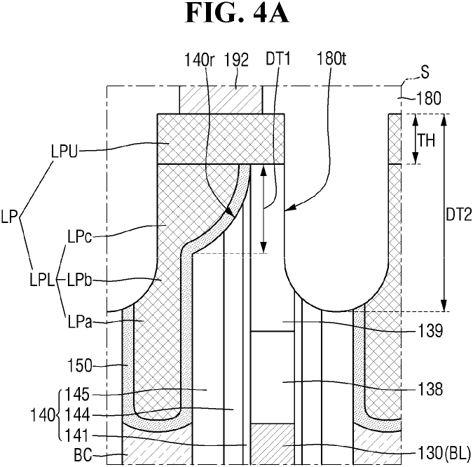

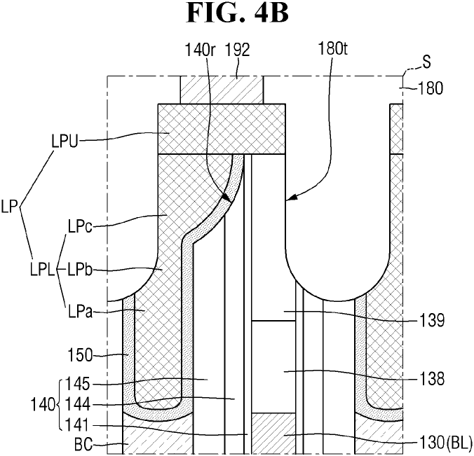

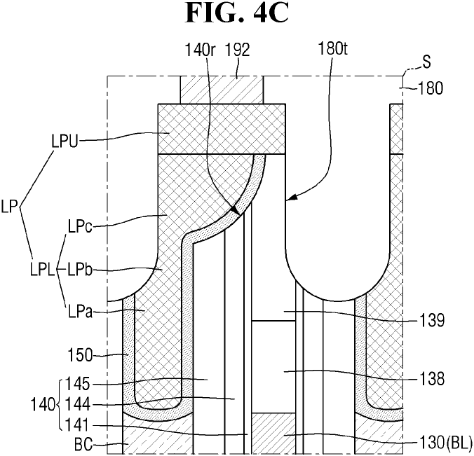

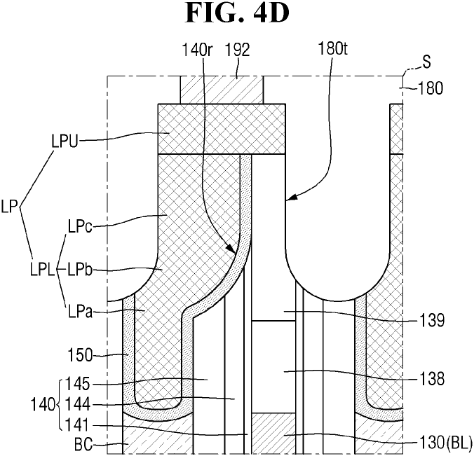

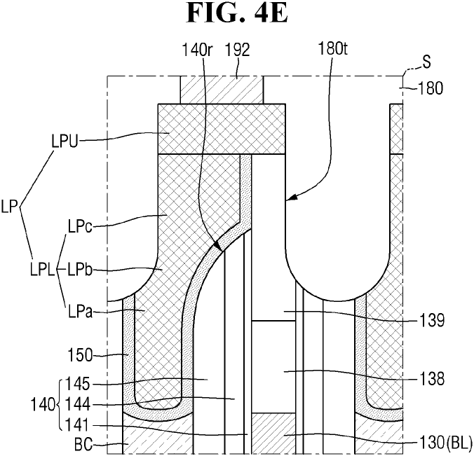

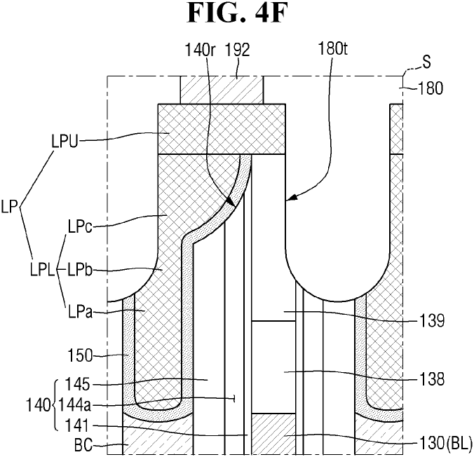

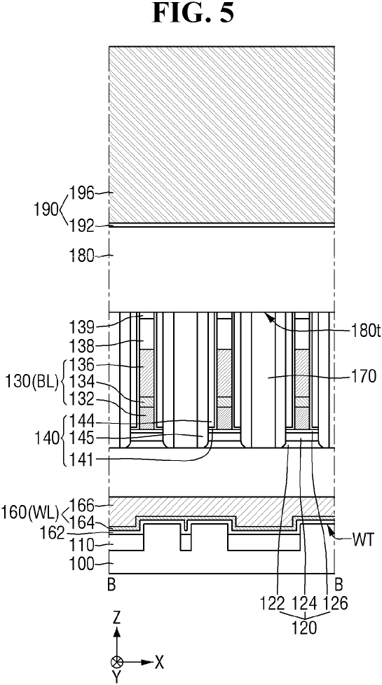

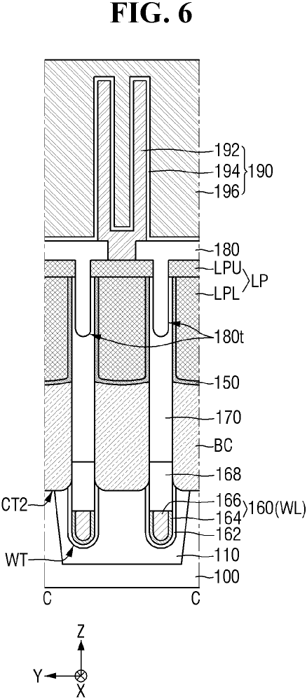

FIG. 1 is an example layout diagram for explaining the semiconductor memory device according to some embodiments. FIG. 2 is a partial layout diagram for explaining a cell region and the core/peri region of FIG. 1. FIG. 3 is a cross-sectional view taken along lines A1-A1 and A2-A2 of FIG. 2. FIGS. 4A to 4F are various enlarged views for explaining a region S of FIG. 3. FIG. 5 is a cross-sectional view taken along a line B-B of FIG. 2. FIG. 6 is a cross-sectional view taken along a line C-C of FIG. 2. FIG. 7 is a cross-sectional view taken along a line D-D of FIG. 2.

Referring to FIG. 1, the semiconductor memory device according to some embodiments includes a cell region CELL and a core/peri region CORE/PERI.

An element separation film 110, a base insulating film 120, a bit line BL, a word line WL, a direct contact DC, a spacer structure 140, a buried contact BC, a landing pad LP, and a capacitor structure 190, which will be described below, may be formed in the cell region CELL to implement semiconductor memory elements on the substrate 100.

The core/peri region CORE/PERI may be placed around the cell region CELL. For example, the core/peri region CORE/PERI may surround the cell region CELL. Control elements and dummy elements such as a peripheral circuit element PC and a wiring pattern BP, which will be described below, may be formed in the core/peri region CORE/PERI to control the functions of the semiconductor memory elements formed in the cell region CELL.

Referring to FIGS. 2 to 7, the semiconductor memory device according to some embodiments includes a substrate 100, an element separation film 110, a base insulating film 120, a bit line BL, first capping patterns 138 and 139, a word line WL, a direct contact DC, a spacer structure 140, a buried contact BC, a first barrier conductive film 150, a landing pad LP, a capacitor structure 190, a peripheral circuit element PC, a second barrier conductive film 250, a contact plug CP, and a wiring pattern BP.

Although the substrate 100 may have a structure in which a base substrate and an epitaxial layer are stacked, the present disclosure is not limited thereto. The substrate 100 may be a silicon substrate, a gallium arsenide substrate, a silicon germanium substrate, or an SOI (Semiconductor On Insulator) substrate. As an example, the substrate 100 will be described below as a silicon substrate.

The substrate 100 may include the active region AR. As the design rules of semiconductor memory devices decrease, the active region AR is formed in the form of a diagonal bar. For example, as shown in FIG. 2, the active region AR has a form of a bar extending in a third direction W different from a first direction Y and a second direction X, in a plane extending in the first direction Y and the second direction X. In some embodiments, the third direction W may form an acute angle θ with the second direction X. The acute angle θ may be, for example, but is not limited to, 60°.

The active region AR may be in the form of multiple bars extending in directions parallel to each other. Further, the center of one of the plurality of active regions AR may be placed to be adjacent to a distal end of the other active region AR.

The active region AR may function as a source/drain region by including impurities. In some embodiments, the center of the active region AR may be electrically connected to the bit line BL by a direct contact DC, and opposite ends of the active region AR may be electrically connected to the capacitor structure 190 by the buried contact BC and the landing pad LP.

The element separation film 110 may define a plurality of active regions AR inside the substrate 100. In FIGS. 2 to 7, although side surfaces of the element separation film 110 are shown to have a slope, this is merely a process feature, and the present disclosure is not limited thereto.

The element separation film 110 may include, but is not limited to, an insulating material, for example, at least one of silicon oxide, silicon nitride, silicon oxynitride, silicon oxycarbonitride, and combinations thereof. The element separation film 110 may be a single film made of one kind of insulating material, or may be a multi-film (e.g., a multi-layer film structure) made of a combination of a plurality of kinds of insulating materials.

The base insulating film 120 may be formed on the substrate 100 and the element separation film 110. The base insulating film 120 may be interposed between the substrate 100 and the bit line BL, and between the element separation film 110 and the bit line BL.

The base insulating film 120 may be a single film, or may be a multi-film as shown. For example, the base insulating film 120 may include a first insulating film 122, a second insulating film 124, and a third insulating film 126 which are sequentially stacked on the substrate 100 and the element separation film 110. As an example, the first insulating film 122 may include silicon oxide. The second insulating film 124 may include a material having an etching selectivity different from that of the first insulating film 122. As an example, the second insulating film 124 may include silicon nitride. The third insulating film 126 may include a material having a smaller dielectric constant than the second insulating film 124. As an example, the third insulating film 126 may include silicon oxide.

The bit line BL may be formed on the substrate 100, the element separation film 110, and the base insulating film 120. The bit line BL may extend long in the first direction Y. For example, the bit line BL may diagonally cross the active region AR and vertically cross the word line WL. The plurality of bit lines BL may be spaced apart at equal intervals and extend in parallel in the first direction Y.

The bit line BL may include a first conductive line 130. The first conductive line 130 may be a single film, or may be multi-films as shown. For example, the first conductive line 130 may include a first conductive pattern 132, a second conductive pattern 134, and a third conductive pattern 136 that are sequentially stacked on the substrate 100. The first conductive pattern 132, the second conductive pattern 134, and the third conductive pattern 136 may each include a conductive material, for example, but is not limited to, at least one of polysilicon, titanium nitride (TiN), titanium silicon nitride (TiSiN), tungsten, tungsten silicide, and a combination thereof. As an example, the first conductive pattern 132 may include polysilicon, the second conductive pattern 134 may include TiSiN, and the third conductive pattern 136 may include tungsten.

The first capping patterns 138 and 139 may be formed on the first conductive line 130. The first capping patterns 138 and 139 may extend along the upper surface of the first conductive line 130. The first capping patterns 138 and 139 may be a single film, or may be multi-films as shown. For example, the first capping patterns 138 and 139 may include a first sub-capping pattern 138 and a second sub-capping pattern 139 that are sequentially stacked on the first conductive line 130. The first sub-capping pattern 138 and the second sub-capping pattern 139 may each include an insulating material, for example, but is not limited to, at least one of silicon oxide, silicon nitride, silicon oxynitride, silicon oxycarbonitride, and a combination thereof. In an example, the first sub-capping pattern 138 and the second sub-capping pattern 139 may each include silicon nitride.

In some embodiments, an etching stop film may be interposed between the first sub-capping pattern 138 and the second sub-capping pattern 139. The etching stop film may include, for example, but is not limited to, silicon nitride (SiN).

The word line WL may be formed on the substrate 100 and the element separation film 110. The word line WL may extend long in the second direction X. The word line WL may also cross the active region AR between the direct contact DC and the buried contact BC. For example, the word line WL may diagonally cross the active region AR and vertically cross the bit line BL. The plurality of word lines WL may be spaced apart at equal intervals and extend in parallel in the second direction X.

The word line WL may include a second conductive line 160. The second conductive line 160 may be a single film, or may be multi-films as shown. For example, the second conductive line 160 may include a fourth conductive pattern 164 and a fifth conductive pattern 166 (FIG. 5) that are sequentially stacked on the substrate 100. The fourth conductive pattern 164 and the fifth conductive pattern 166 may include, for example, but are not limited to, at least one of metal, polysilicon, and a combination thereof, respectively. As an example, the fourth conductive pattern 164 may include TiN, and the fifth conductive pattern 166 may include polysilicon doped with n-type impurities.

A word line dielectric film 162 (FIG. 5) may be interposed between the second conductive line 160 and the active region AR of the substrate 100. The word line dielectric film 162 may include, for example, but is not limited to, silicon oxide, silicon oxynitride, silicon nitride, and a high dielectric constant (high-k) material having a higher dielectric constant than silicon oxide.

A second capping pattern 168 (FIG. 6) may be formed on the second conductive line 160. The second capping pattern 168 may extend along the upper surface of the second conductive line 160. The second capping pattern 168 may include, but is not limited to, insulating materials, for example, at least one of silicon oxide, silicon nitride, silicon oxynitride, silicon oxycarbonitride, and combinations thereof. The second capping pattern 168 may be a single film or multi-films made up of a combination of a plurality of types of insulating materials.

In some embodiments, the word line WL may be embedded inside the substrate 100. For example, the substrate 100 may include a gate trench WT (FIG. 5) extending in the second direction X. The word line dielectric film 162 may extend along a profile of the gate trench WT. The second conductive line 160 may fill a part of the gate trench WT on the word line dielectric film 162. The second capping pattern 168 may fill another part of the gate trench WT on the second conductive line 160. In this case, the upper surface of the second conductive line 160 may be formed to be lower than the upper surface of the substrate 100.

The direct contact DC may be formed on the substrate 100 and the element separation film 110. The direct contact DC may connect the active region AR of the substrate 100 and the bit line BL. For example, the substrate 100 may include a first contact trench CT1 that penetrates the base insulating film 120 and exposes a first portion of the active region AR. The direct contact DC is formed inside the first contact trench CT1, and may connect the active region AR of the substrate 100 and the first conductive line 130.

In some embodiments, the first contact trench CT1 may expose the center of each active region AR. Therefore, the direct contact DC may be electrically connected to the center of the active region AR. In some embodiments, a part of the first contact trench CT1 may overlap a part of the element separation film 110. Accordingly, the first contact trench CT1 may expose not only a part of the active region AR but also a part of the element separation film 110.

In some embodiments, the width of the direct contact DC may be smaller than the width of the first contact trench CT1. For example, as shown in FIG. 3, the direct contact DC may only come into contact with a part of the substrate 100 exposed by the first contact trench CT1. In some embodiments, the width of the bit line BL may also be smaller than the width of the first contact trench CT1. For example, the width of the bit line BL may be the same as the width of the direct contact DC.

The direct contact DC may include, but is not limited to, conductive materials, for example, at least one of polysilicon, TiN, TiSiN, tungsten, tungsten silicide, and combinations thereof. In an example, the direct contact DC may include polysilicon. The bit line BL may be electrically connected to the active region AR of the substrate 100 through the direct contact DC. The active region AR of the substrate 100 electrically connected to the direct contact DC may function as a source/drain region of the semiconductor element including the word line WL.

The spacer structure 140 may be formed on the side surfaces of the bit line BL. The spacer structure 140 may extend along the side surfaces of the first conductive line 130 and the side surfaces of the first capping patterns 138 and 139. In some embodiments, the height of the spacer structure 140 may be formed to be equal to or lower than the uppermost surfaces of the first capping patterns 138 and 139.

The spacer structure 140 may include, but is not limited to, insulating materials, for example, at least one of silicon oxide, silicon nitride, silicon oxynitride, silicon oxycarbonitride, and combinations thereof. In some embodiments, the spacer structure 140 may be multi-films made up of a combination of several types of insulating materials. For example, the spacer structure 140 may include a base spacer 141, a first lower spacer 142, a second lower spacer 143, a first side spacer 144, and a second side spacer 145.

The base spacer 141 may be formed on the side surfaces of the bit line BL. For example, the base spacer 141 may conformally extend along the profile of at least a part of the side surfaces of the first conductive line 130 and the side surfaces of the first capping patterns 138 and 139. In some embodiments, the base spacer 141 may be the innermost spacer of the spacer structure 140 that is in contact with the bit line BL and the direct contact DC.

In some embodiments, the base spacer 141 of a region in which the first contact trench CT1 is not formed may extend along the side surfaces of the bit line BL and the upper surface of the base insulating film 120. In some embodiments, the base spacer 141 of the region in which the first contact trench CT1 is formed may extend along the side surfaces of the bit line BL, the side surfaces of the direct contact DC, and the first contact trench CT1.

The first lower spacer 142 may be formed on the base spacer 141 inside the first contact trench CT1. For example, the first lower spacer 142 may conformally extend along the profile of the base spacer 141 inside the first contact trench CT1.

The second lower spacer 143 may be formed on the first lower spacer 142 inside the first contact trench CT1. For example, the second lower spacer 143 may fill the region of the first contact trench CT1 which remains after the base spacer 141 and the first lower spacer 142 are formed.

The first side spacer 144 may be formed on the outer surface of the base spacer 141. Further, the first side spacer 144 may be formed on the first lower spacer 142 and the second lower spacer 143. For example, the first side spacer 144 may conformally extend along the profile of a part of the side surfaces of the first capping patterns 138 and 139 and the side surfaces of the first conductive line 130.

The second side spacer 145 may be formed on the outer surface of the first side spacer 144. Further, the first side spacer 144 may be formed on the second lower spacer 143. For example, the second side spacer 145 may conformally extend along the profile of a part of the side surfaces of the first capping patterns 138 and 139 and the side surfaces of the first conductive line 130. In some embodiments, the second side spacer 145 may be the outermost spacer of the spacer structure 140 that is in contact with the buried contact BC.

In some embodiments, a lower surface of the second side spacer 145 may be formed to be lower than the uppermost surface of the second lower spacer 143.

The base spacer 141, the first lower spacer 142, the second lower spacer 143, the first side spacer 144, and the second side spacer 145 may each include an insulating material, for example, but are not limited to, at least one of silicon oxide, silicon nitride, silicon oxynitride, silicon oxycarbonitride, and combinations thereof.

In some embodiments, the first lower spacer 142 may include a different material from that of the base spacer 141 and/or the second lower spacer 143. For example, the first lower spacer 142 may include an insulating material having a lower dielectric constant than that of the base spacer 141 and/or the second lower spacer 143. In an example, the first lower spacer 142 may include silicon oxide, and the base spacer 141 and the second lower spacer 143 may each include silicon nitride.

In some embodiments, the first side spacer 144 may include a different material from that of the base spacer 141 and/or the second side spacer 145. For example, the first side spacer 144 may include an insulating material having a lower dielectric constant than that of the base spacer 141 and/or the second side spacer 145. In an example, the first side spacer 144 may include silicon oxide, and the base spacer 141 and the second side spacer 145 may each include silicon nitride.

An upper part of the spacer structure 140 may include a spacer recess 140r, which may be a sloped/curved region of the spacer structure 140. The spacer recess 140r may be formed to be lower than or equal to the uppermost surfaces of the first capping patterns 138 and 139. Further, the spacer recess 140r may be formed to be deeper as it goes away from the side surfaces of the first capping patterns 138 and 139. For example, the height of the spacer structure 140 may decrease as it goes away from the side surfaces of the first capping patterns 138 and 139. In some embodiments, the height of the uppermost part of the spacer recess 140r may be the same as the height of the uppermost surfaces of the first capping patterns 138 and 139. In the present specification, the meaning of the term “same” includes not only exactly the same thing but also minute differences that may occur due to process margins and the like.

In some embodiments, the spacer recess 140r may have an upward concave shape. This may be due to the characteristics of the etching process for forming the spacer recess 140r.

In some embodiments, the spacer recess 140r may be defined by the upper surface of the base spacer 141, the upper surface of the first side spacer 144, and the upper surface of the second side spacer 145. For example, the height of the base spacer 141, the height of the first side spacer 144, and the height of the second side spacer 145 may gradually decrease, as they go away from the side surfaces of the first capping patterns 138 and 139.

The buried contact BC may be formed on the substrate 100 and the element separation film 110. The buried contact BC may connect the active region AR of the substrate 100 and the landing pad LP. For example, the substrate 100 may include a second contact trench CT2 that penetrates the base insulating film 120 and exposes the second portion of the active region AR. The buried contact BC is formed in the second contact trench CT2 and may connect the active region AR of the substrate 100 and the landing pad LP.

In some embodiments, the second contact trench CT2 may expose opposite ends of each active region AR. Therefore, the buried contact BC may be electrically connected to opposite ends of the active region AR. In some embodiments, a part of the second contact trench CT2 may overlap a part of the element separation film 110. Accordingly, the second contact trench CT2 may expose not only a part of the active region AR but also a part of the element separation film 110.

The buried contact BC may be formed on the side surfaces of the bit line BL. Further, the buried contact BC may be spaced apart from the bit line BL by the spacer structure 140. For example, as shown in FIG. 3, the buried contact BC may extend along a part of the outer surface of the spacer structure 140. The plurality of buried contacts BC arranged along the second direction X may be spaced apart from each other by the bit line BL extending long in the first direction Y and the spacer structure 140. In some embodiments, the upper surface of the buried contact BC may be formed to be lower than the upper surfaces of the first capping patterns 138 and 139.

The buried contact BC may be formed on the side surfaces of the word line WL. For example, as shown in FIG. 6, an insulating fence 170 extending in the second direction X may be formed on the second capping pattern 168. The buried contact BC may extend along a part of the side surfaces of the second capping pattern 168 or a part of the side surfaces of the insulating fence 170. The plurality of buried contacts BC arranged along the first direction Y may be spaced apart from each other by the second capping pattern 168 and/or the insulating fence 170 extending in the second direction X.

Such buried contacts BC may form a plurality of isolated regions that are spaced apart from each other. For example, as shown in FIG. 2, a plurality of buried contacts BC may be interposed between a plurality of bit lines BL and a plurality of word lines WL. In some embodiments, the buried contacts BC may be arranged as a lattice structure.

The buried contacts BC may include, but are not limited to, conductive materials, for example, at least one of polysilicon, TiN, TiSiN, tungsten, tungsten silicide, and combinations thereof. In an example, the buried contact BC may include polysilicon. The landing pad LP may be electrically connected to the active region AR of the substrate 100 through the buried contact BC. The active region AR of the substrate 100 electrically connected to the buried contact BC may function as a source/drain region of the semiconductor element including the word line WL.

The first barrier conductive film 150 may be formed on the buried contact BC. Further, the first barrier conductive film 150 may extend along the spacer structure 140 and the insulating fence 170. The first barrier conductive film 150 may be interposed between the buried contact BC and the landing pad LP, between the spacer structure 140 and the landing pad LP, and between the insulating fence 170 and the landing pad LP. For example, the first barrier conductive film 150 may extend conformally along the profile of the upper surface of the buried contact BC, a part of the side surfaces of the spacer structure 140, the upper surface of the spacer structure 140, and a part of the side surfaces of the insulating fence 170.

A part of the first barrier conductive film 150 may extend along the spacer recess 140r. Therefore, the first barrier conductive film 150 may come into contact with not only the second side spacer 145 but also the first side spacer 144 and/or the base spacer 141. In some embodiments, a part of the first barrier conductive film 150 extends along the spacer recess 140r, and may come into contact with the upper surface of the base spacer 141, the upper surface of the first side spacer 144, and the upper surface of the second side spacer 145.

The first barrier conductive film 150 may expose (i.e., may not cover/contact) the uppermost surfaces of the first capping patterns 138 and 139. For example, as shown in FIG. 4A, the upper part of the first barrier conductive film 150 extends along the spacer recess 140r, and may not extend along the uppermost surfaces of the first capping patterns 138 and 139. In some embodiments, the upper surface of the first barrier conductive film 150 may be coplanar with the upper surfaces of the first capping patterns 138 and 139 (e.g., coplanar with the upper surface of the second sub-capping pattern 139). In some embodiments, the upper part of the first barrier conductive film 150 may come into contact with the side surfaces of the first capping patterns 138 and 139. Moreover, the landing pad LP may contact the uppermost surface of the first capping patterns 138 and 139 (e.g., the upper surface of the second sub-capping pattern 139).

The first barrier conductive film 150 may include a metal or a metal nitride for inhibiting/preventing diffusion of the landing pad LP. For example, the first barrier conductive film 150 may include, but is not limited to, at least one of titanium (Ti), tantalum (Ta), tungsten (W), nickel (Ni), cobalt (Co), platinum (Pt), alloys thereof, and nitrides thereof. As an example, the first barrier conductive film 150 may include titanium nitride (TiN).

The landing pad LP may be formed on the first barrier conductive film 150. Further, the landing pad LP may be electrically connected to the buried contact BC. In some embodiments, the landing pad LP may be placed to overlap at least a part of the buried contact BC. Here, the overlap means the overlap in the vertical direction (hereinafter, a fourth direction Z) intersecting the upper surface of the substrate 100. For example, as shown in FIGS. 2 and 3, a first part of the landing pad LP may overlap the buried contact BC, and a second part of the landing pad LP may overlap a part of the spacer structure 140 and a part of the first capping patterns 138 and 139.

The landing pad LP may include, but is not limited to, conductive materials, for example, at least one of polysilicon, TiN, TiSiN, tungsten, tungsten silicide, and combinations thereof. In an example, the landing pad LP may include tungsten (W). The capacitor structure 190 may be electrically connected to the active region AR of the substrate 100 through the buried contact BC and the landing pad LP.

The landing pad LP may form a plurality of isolated regions spaced apart from each other. For example, as shown in FIG. 3, a pad trench 180t that defines a plurality of landing pads LP may be formed. The pad trench 180t may extend from the upper surface of the landing pad LP, and a lower surface thereof may be formed to be lower than the upper surface of the spacer structure 140. Further, at least a part of the pad trench 180t may be placed to overlap at least a part of the spacer structure 140. For example, the pad trench 180t may overlap a part of the spacer structure 140 and a part of the first capping patterns 138 and 139. Therefore, a plurality of landing pads LP may be separated from each other by the pad trench 180t.

In some embodiments, a depth DT2 of the pad trench 180t may be formed to be deeper than a depth DT1 of the spacer recess 140r. Accordingly, the lower surface of the pad trench 180t may be formed to be lower than the upper surface of the spacer structure 140. The depth DT2 of the pad trench 180t may be, for example, but is not limited to, from about 200 angstroms (Å) to about 400 Å. In some embodiments, the depth DT2 of the pad trench 180t may be from about 250 Å to about 380 Å.

In some embodiments, the first separation insulating film 180 that is in (e.g., that fills) the pad trench 180t may be formed. The first separation insulating film 180 may include at least one of an insulating material, for example, but is not limited to, at least one of silicon oxide, silicon oxynitride, silicon nitride, and a low dielectric constant (low-k) material having a smaller dielectric constant than that of silicon oxide. The plurality of landing pads LP may be electrically separated from each other by the first separation insulating film 180.

In some embodiments, a plurality of landing pads LP may be arranged in a honeycomb structure. The landing pads LP arranged in the honeycomb structure may further improve the degree of integration of the semiconductor memory device.

In some embodiments, the landing pad LP may include a lower pad LPL and an upper pad LPU.

The lower pad LPL may be formed on the first barrier conductive film 150. Further, the lower pad LPL may be formed on the upper surface of the buried contact BC, the side surfaces of the spacer structure 140, the side surfaces of the first capping patterns 138 and 139, and the side surfaces of the insulating fence 170. The uppermost surface of the lower pad LPL may be formed to be the same as or lower than the uppermost surfaces of the first capping patterns 138 and 139. In some embodiments, the uppermost surface of the lower pad LPL may be coplanar with the uppermost surfaces of the first capping patterns 138 and 139. The plurality of lower pads LPL may be separated from each other by the spacer structure 140 and the first capping patterns 138 and 139.

The upper pad LPU may be formed on the lower pad LPL. Further, the upper pad LPU may be formed on the first barrier conductive film 150 and the first capping patterns 138 and 139. The plurality of upper pads LPU may be separated from each other by the pad trench 180t. In some embodiments, the upper pad LPU may come into contact with the uppermost surface of the first barrier conductive film 150 and the uppermost surfaces of the first capping patterns 138 and 139. As described above, since the first barrier conductive film 150 may not extend along the upper surfaces of the first capping patterns 138 and 139, the first barrier conductive film 150 may not be exposed by (e.g., may not be adjacent) the pad trench 180t. For example, the first barrier conductive film 150 may be spaced apart from the first separation insulating film 180 by the first capping patterns 138 and 139.

A thickness TH of the upper pad LPU may be, for example, but is not limited to, from about 150 Å to about 400 Å. In some embodiments, the depth DT2 of the pad trench 180t may be from about 200 Å to about 300 Å.

In some embodiments, the lower pad LPL and the upper pad LPU may be formed by different deposition processes from each other. In an example, the lower pad LPL may be formed by a chemical vapor deposition (CVD) process, and the upper pad LPU may be formed by a physical vapor deposition (PVD) process.

In some embodiments, the lower pad LPL and the upper pad LPU may include the same conductive material as each other. In an example, the lower pad LPL and the upper pad LPU may each include tungsten (W).

Although only an example in which a boundary is formed between the lower pad LPL and the upper pad LPU is shown, this is merely for convenience of explanation. In some embodiments, depending on the process of forming the lower pad LPL and the upper pad LPU, a boundary may not be formed between the lower pad LPL and the upper pad LPU.

In some embodiments, the landing pad LP may include a tail LPa, a neck LPb, and a head LPc. The tail LPa, the neck LPb, and the head LPc may be included in the lower pad LPL of the landing pad LP.

The tail LPa may be formed on the buried contact BC. The tail LPa may be a lower part of the lower pad LPL placed to be lower than the lowermost surface of the pad trench 180t.

The neck LPb may be formed on the tail LPa. The neck LPb may be an intermediate part of the lower pad LPL that connects the tail LPa and the head LPc. The neck LPb may have a narrower width than the tail LPa. For example, a part of the landing pad LP may be removed by the pad trench 180t. Therefore, the neck LPb having a relatively narrow width may be formed between the pad trench 180t and the side surfaces of the spacer structure 140.

The head LPc may be formed on the neck LPb. The head LPc may be an upper part of the lower pad LPL connected to (e.g., contacting/integrated with) the upper pad LPU. The head LPc may have a width greater than the neck LPb. For example, a part of the head LPc may be formed on the spacer recess 140r.

The capacitor structure 190 may be formed on the first separation insulating film 180 and the landing pad LP. The capacitor structure 190 may be electrically connected to the upper surface of the landing pad LP. For example, the first separation insulating film 180 may be patterned to expose at least a part of the upper surface of the landing pad LP. The capacitor structure 190 may be on and electrically connected to at least a part of the upper surface of the landing pad LP exposed by the first separation insulating film 180. Therefore, the capacitor structure 190 may be electrically connected to the active region AR of the substrate 100 through the buried contact BC and the landing pad LP. The capacitor structure 190 may be controlled by the bit line BL and the word line WL and may store data.

In some embodiments, the capacitor structure 190 may include a lower electrode 192, a capacitor dielectric film 194, and an upper electrode 196 that are sequentially stacked on the landing pad LP. The capacitor structure 190 may store electric charges inside the capacitor dielectric film 194, using a potential difference that occurs between the lower electrode 192 and the upper electrode 196.

The lower electrode 192 and the upper electrode 196 may include, but are not limited to, for example, doped polysilicon, metal or metal nitride. Further, the capacitor dielectric film 194 may include, but is not limited to, for example, silicon oxide or a high dielectric constant material.

The peripheral circuit element PC may be formed on the substrate 100 of the core/peri region CORE/PERI. The peripheral circuit element PC may control the functions of the semiconductor memory elements formed in the cell region CELL. The peripheral circuit element PC may include not only various active elements such as transistors, but also various passive elements such as capacitors, resistors and inductors.

For example, the peripheral circuit element PC may include a gate dielectric film 220, a gate electrode 230, a gate capping pattern 238, and a gate spacer 240.

The gate electrode 230 may be a single film, or may be multi-films as shown. For example, the gate electrode 230 may include a sixth conductive pattern 232, a seventh conductive pattern 234, and an eighth conductive pattern 236 that are sequentially stacked on the substrate 100. The sixth conductive pattern 232, the seventh conductive pattern 234, and the eighth conductive pattern 236 may each include a conductive material, for example, but is not limited to, at least one of polysilicon, TiN, TiSiN, tungsten, tungsten silicide, and combinations thereof. As an example, the sixth conductive pattern 232 may include polysilicon, the seventh conductive pattern 234 may include TiSiN, and the eighth conductive pattern 236 may include tungsten.

In some embodiments, the first conductive line 130 and the gate electrode 230 may be formed at the same level. As used herein, the term “same level” means formation by the same fabricating process. For example, the first conductive pattern 132 and the sixth conductive pattern 232 may include the same material, the second conductive pattern 134 and the seventh conductive pattern 234 may include the same material, and the third conductive pattern 136 and the eighth conductive pattern 236 may include the same material as each other.

The gate dielectric film 220 may be interposed between the gate electrode 230 and the substrate 100. The gate dielectric film 220 may include, for example, but is not limited to, at least one of silicon oxide, silicon oxynitride, silicon nitride, and a high dielectric constant (high-k) material having a higher dielectric constant than silicon oxide.

The gate capping pattern 238 may be formed on the gate electrode 230. The gate capping pattern 238 may extend along the upper surface of the gate electrode 230. The gate capping pattern 238 may include, but is not limited to, insulating materials, for example, at least one of silicon oxide, silicon nitride, silicon oxynitride, silicon oxycarbonitride, and combinations thereof. In an example, the gate capping pattern 238 may include silicon nitride. In some embodiments, the first sub-capping pattern 138 and the gate capping pattern 238 may be formed at the same level.

The gate spacer 240 may be formed on the side surfaces of the gate electrode 230. The gate spacer 240 may extend along the side surfaces of the gate electrode 230. The gate spacer 240 may include, but is not limited to, insulating materials, for example, at least one of silicon oxide, silicon nitride, silicon oxynitride, silicon oxycarbonitride, and combinations thereof.

In some embodiments, a liner film 225 extending along the upper surface of the substrate 100, the upper surface of the element separation film 110, and the side surfaces of the gate spacer 240 may be formed. The liner film 225 may function as, but is not limited to, an etching blocking film.

In some embodiments, the first interlayer insulating film 245 and the second interlayer insulating film 239 may be formed on the substrate 100 of the core/peri region CORE/PERI. The first interlayer insulating film 245 and the second interlayer insulating film 239 may be sequentially stacked on the substrate 100 and the peripheral circuit element PC. For example, the first interlayer insulating film 245 may cover the upper surface and the side surfaces of the liner film 225. The second interlayer insulating film 239 may cover the upper surface of the gate capping pattern 238 and the upper surface of the first interlayer insulating film 245. In some embodiments, the second sub-capping pattern 139 and the second interlayer insulating film 239 may be formed at the same level.

The contact plug CP may be formed on the side surfaces of the peripheral circuit element PC. The contact plug CP may connect the peripheral circuit element PC and the wiring pattern BP. For example, the contact plug CP may penetrate the second interlayer insulating film 239 and the first interlayer insulating film 245 to connect the substrate 100 on the side surfaces of the peripheral circuit element PC and the wiring pattern BP. Alternatively, unlike the shown example, the contact plug CP may penetrate the second interlayer insulating film 239 and the gate capping pattern 238 to connect the gate electrode 230 and the wiring pattern BP. In some embodiments, the uppermost surface of the contact plug CP may be coplanar with the uppermost surface of the second interlayer insulating film 239.

The contact plug CP may include, but is not limited to, conductive materials, for example, at least one of polysilicon, TiN, TiSiN, tungsten, tungsten silicide, and combinations thereof. In an example, the contact plug CP may include tungsten (W). The wiring pattern BP may be electrically connected to the peripheral circuit element PC through the contact plug CP. In some embodiments, the lower pad LPL and the contact plug CP may be formed at the same level.

The second barrier conductive film 250 may be interposed between the substrate 100 and the contact plug CP, between the liner film 225 and the contact plug CP, between the first interlayer insulating film 245 and the contact plug CP, and/or between the second interlayer insulating film 239 and the contact plug CP. For example, the second barrier conductive film 250 may conformally extend along the profiles of the lower surface and side surfaces of the contact plug CP.

The second barrier conductive film 250 may expose (e.g., may not cover/contact) the uppermost surface of the second interlayer insulating film 239. For example, the second barrier conductive film 250 may not extend along the uppermost surface of the second interlayer insulating film 239. In some embodiments, the uppermost surface of the second barrier conductive film 250 may be coplanar with the uppermost surface of the second interlayer insulating film 239.

The second barrier conductive film 250 may include a metal or a metal nitride for inhibiting/preventing the diffusion of the contact plug CP. For example, the second barrier conductive film 250 may include, but is not limited to, at least one of titanium (Ti), tantalum (Ta), tungsten (W), nickel (Ni), cobalt (Co), platinum (Pt), their alloys, and their nitrides. As an example, the second barrier conductive film 250 may include titanium nitride (TiN). In some embodiments, the first barrier conductive film 150 and the second barrier conductive film 250 may be formed at the same level.

The wiring pattern BP may be formed on the peripheral circuit element PC. For example, the wiring pattern BP may extend along the upper surface of the second interlayer insulating film 239. The wiring pattern BP may include, but is not limited to, conductive materials, for example, at least one of polysilicon, TiN, TiSiN, tungsten, tungsten silicide, and combinations thereof. As an example, the wiring pattern BP may include tungsten (W). In some embodiments, the upper pad LPU and the wiring pattern BP may be formed at the same level.

The wiring pattern BP may form a plurality of wirings that are spaced apart from each other. For example, as shown in FIG. 3, a wiring trench 280t that defines a plurality of wiring patterns BP may be formed. The wiring trench 280t may extend from the upper surface of the wiring pattern BP, and may have a lower surface formed to be lower than the lower surface of the wiring pattern BP. The plurality of wiring patterns BP may be separated from each other by the wiring trench 280t.

In some embodiments, a second separation insulating film 280 that is in (e.g., that fills) the wiring trench 280t may be formed. The second separation insulating film 280 may include an insulating material, for example, but is not limited to, at least one of silicon oxide, silicon oxynitride, silicon nitride, and a low dielectric constant (low-k) material having a smaller dielectric constant than silicon oxide. The plurality of wiring patterns BP may be electrically separated from each other by the second separation insulating film 280. In some embodiments, the second separation insulating film 280 may be formed at the same level as the first separation insulating film 180.

Referring to FIG. 4B, in the semiconductor memory device according to some embodiments, the spacer recess 140r exposes a part of the outer surface of the base spacer 141.

For example, the spacer recess 140r may be defined by the upper surface of the first side spacer 144 and the upper surface of the second side spacer 145. The spacer recess 140r may not be defined by the upper surface of the base spacer 141. For example, the height of the base spacer 141 may be the same as the height of the uppermost surfaces of the first capping patterns 138 and 139.

The first barrier conductive film 150 may expose (e.g., may not cover/contact) the upper surface of the base spacer 141. For example, the upper part of the first barrier conductive film 150 extends along the spacer recess 140r, and may not extend along the uppermost surface of the base spacer 141. In some embodiments, the uppermost surface of the first barrier conductive film 150 may be coplanar with the uppermost surface of the base spacer 141. In some embodiments, the upper part of the first barrier conductive film 150 may be in contact with the outer surface (e.g., a side surface) of the base spacer 141.

Referring to FIG. 4C, in the semiconductor memory device according to some embodiments, the spacer recess 140r exposes a part of the first capping patterns 138 and 139.

For example, the spacer recess 140r may be defined by the upper surface of a part of the first capping patterns 138 and 139, an upper surface of the base spacer 141, an upper surface of the first side spacer 144, and an upper surface of the second side spacer 145.

The first barrier conductive film 150 may come into contact with the first capping patterns 138 and 139. For example, the upper part of the first barrier conductive film 150 extends along the spacer recess 140r and may come into contact with the upper parts of the first capping patterns 138 and 139 (e.g., a sloped/curved upper portion of the second sub-capping pattern 139).

Referring to FIG. 4D, in the semiconductor memory device according to some embodiments, the spacer recess 140r is formed to be lower than the uppermost surfaces of the first capping patterns 138 and 139.

For example, the upper side surfaces of the first capping patterns 138 and 139 may be exposed by the spacer structure 140. The first barrier conductive film 150 may further extend along the side surfaces of the first capping patterns 138 and 139 exposed by the spacer structure 140. Such a first barrier conductive film 150 may come into contact with the upper side surfaces of the first capping patterns 138 and 139 (e.g., an upper portion of a straight side surface of the second sub-capping pattern 139).

Referring to FIG. 4E, in the semiconductor memory device according to some embodiments, the spacer recess 140r (and thus an upper portion of the first barrier conductive film 150) has an upward convex shape. This may be due to the characteristics of the etching process for forming the spacer recess 140r.

In some embodiments, the spacer recess 140r may be formed to be lower than the uppermost surfaces of the first capping patterns 138 and 139.

Referring to FIG. 4F, in the semiconductor memory device according to some embodiments, the spacer structure 140 includes an air spacer 144a.

The air spacer 144a may consist of air or a void. Since the air spacer 144A has a smaller dielectric constant than silicon oxide, the parasitic capacitance of the semiconductor memory device can be effectively reduced.

In some embodiments, the first barrier conductive film 150 may cover the upper surface of the air spacer 144a. For example, the first barrier conductive film 150 extending along the spacer recess 140r may define the upper surface of the air spacer 144a.

In some embodiments, the air spacer 144a may be interposed between the base spacer 141 and the second side spacer 145. For example, the air spacer 144a may be formed by removing the first side spacer 144 of FIG. 4A. In such a case, the air spacer 144a may be defined by the outer surface of the base spacer 141, the inner surface of the second side spacer 145, and the lower surface of the first barrier conductive film 150.

Hereinafter, a method for fabricating a semiconductor memory device according to example embodiments will be described referring to FIGS. 1 to 23.

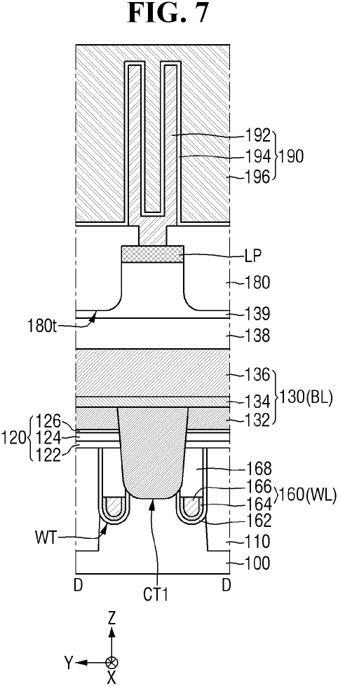

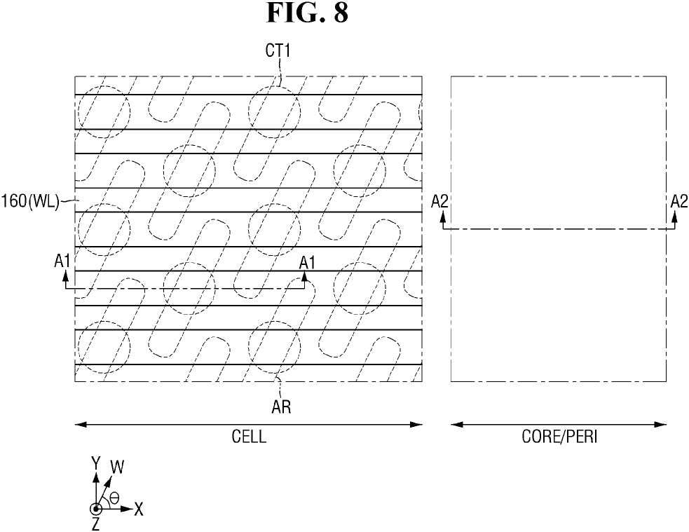

FIGS. 8 to 23 are intermediate step diagrams for explaining a method for fabricating a semiconductor memory device according to some embodiments. For convenience of explanation, repeated parts of those described above using FIGS. 1 to 7 may be briefly described or omitted.

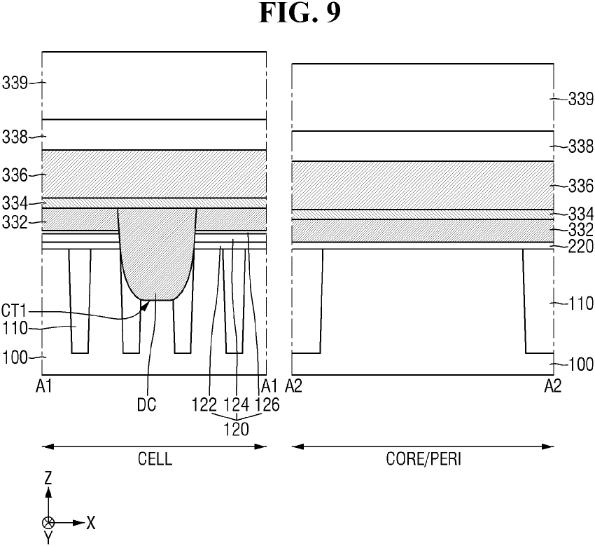

Referring to FIGS. 8 and 9, a base insulating film 120, a first conductive film 332, a direct contact DC, a second conductive film 334, a third conductive film 336, a first capping film 338, and a second capping film 339 are formed on the substrate 100 and the element separation film 110.

For example, the first insulating film 122 may be formed on the substrate 100 of the cell region CELL, and the gate dielectric film 220 may be formed on the substrate 100 of the core/peri region CORE/PERI. Although the first insulating film 122 and the gate dielectric film 220 may be formed at the same level, the present inventive concept is not limited thereto. Subsequently, the second insulating film 124 and the third insulating film 126 may be sequentially formed on the first insulating film 122 of the cell region CELL. Subsequently, the first conductive film 332 may be formed on the third insulating film 126 of the cell region CELL and the gate dielectric film 220 of the core/peri region CORE/PERI.

Next, a first contact trench CT1 that exposes a first portion of the active region AR (for example, a center of the active region AR) may be formed on the substrate 100 of the cell region CELL. In some embodiments, the first contact trench CT1 may expose the center of the active region AR. Next, the direct contact DC that is in (e.g., that fills) the first contact trench CT1 may be formed.

Subsequently, the second conductive film 334, the third conductive film 336, the first capping film 338, and the second capping film 339 may be formed sequentially on the first conductive film 332 of the cell region CELL and the core/peri region CORE/PERI.

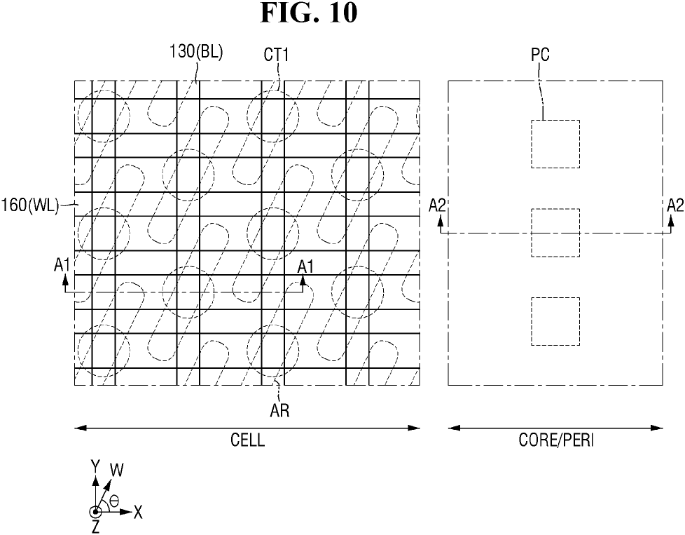

Referring to FIGS. 10 and 11, the first conductive film 332, the direct contact DC, the second conductive film 334, the third conductive film 336, the first capping film 338 and the second capping film 339 are patterned (e.g., etched).

Therefore, the first conductive line 130 (or the bit line BL) and the first capping patterns 138 and 139 extending long in the first direction Y may be formed on the substrate 100 of the cell region CELL.

Further, the peripheral circuit element PC may be formed on the substrate 100 in the core/peri region CORE/PERI. In some embodiments, the liner film 225, the first interlayer insulating film 245, and the second interlayer insulating film 239 may be further formed on the peripheral circuit element PC.

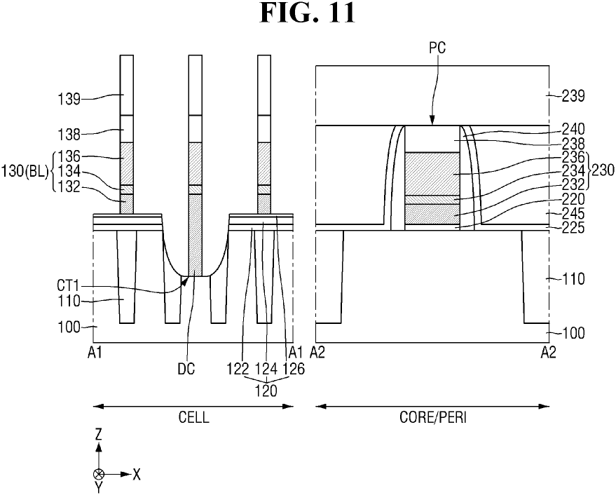

Referring to FIG. 12, a base spacer 141, a first lower spacer 142, a second lower spacer 143, and a first side spacer 144 are formed on the side surfaces of the bit line BL.

For example, the base spacer 141 extending conformally may be formed on the resulting product of FIG. 11. Subsequently, the first lower spacer 142 and the second lower spacer 143 may be sequentially formed on the base spacer 141 inside the first contact trench CT1. Next, a first side spacer 144 that extends conformally along the base spacer 141, the first lower spacer 142, and the second lower spacer 143 may be formed.

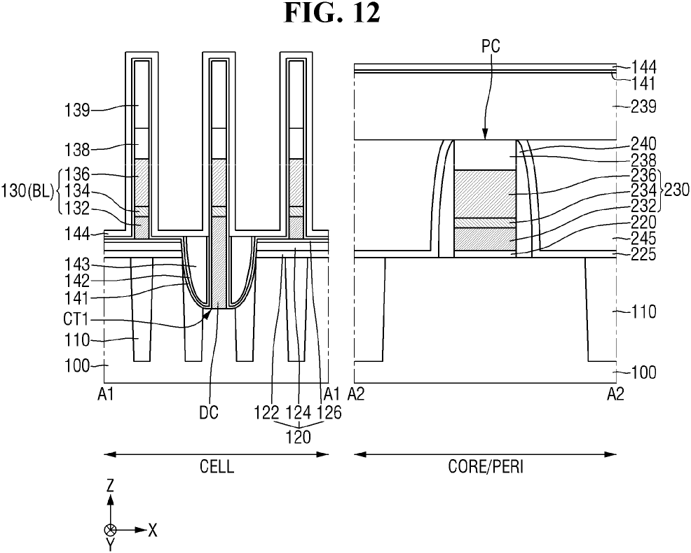

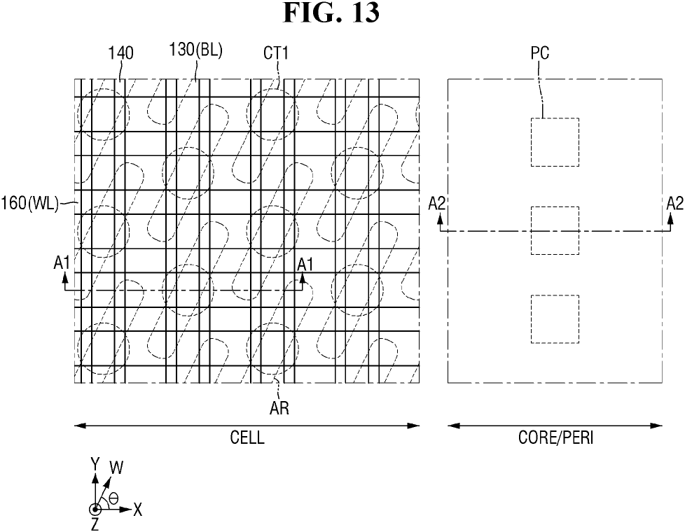

Referring to FIGS. 13 and 14, the second side spacer 145 is formed on the side surface of the bit line BL.

For example, an etching process of removing a part of the base insulating film 120 interposed between the plurality of bit lines BL may be performed. In the etching process, a part of the first side spacer 144 extending along the outer surface of the base spacer 141 may remain without being removed. Next, the second side spacer 145 that extends conformally may be formed. Accordingly, the spacer structure 140 which includes the base spacer 141, the first lower spacer 142, the second lower spacer 143, the first side spacer 144, and the second side spacer 145 is formed.

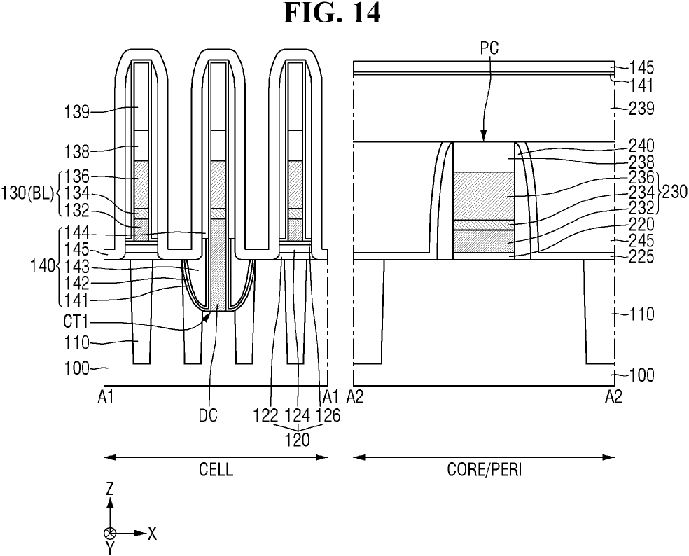

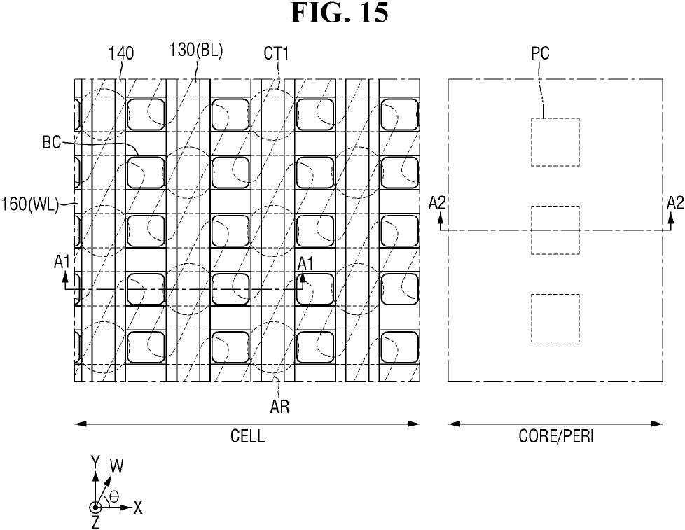

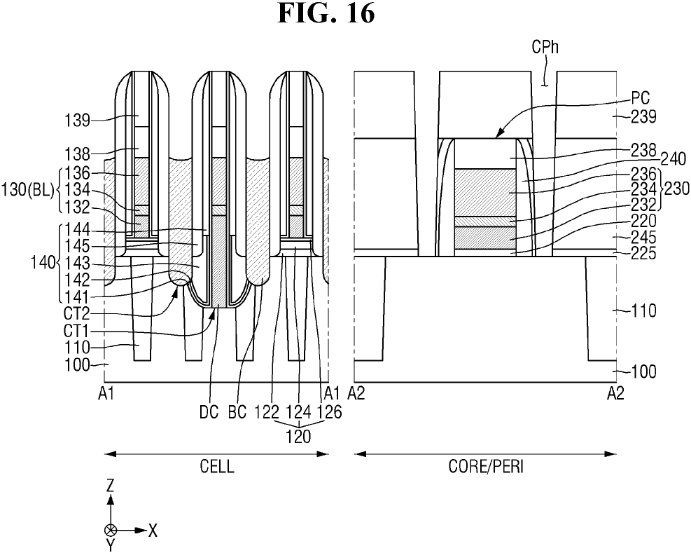

Referring to FIGS. 15 and 16, the buried contact BC is formed on the substrate 100 and the element separation film 110.

For example, a second contact trench CT2 that exposes a second portion of the active region AR (e.g., opposite ends of the active region AR) may be formed inside the substrate 100 of the cell region CELL. Next, the buried contact BC that is in (e.g., that fills) the second contact trench CT2 may be formed.

The upper surface of the buried contact BC may be formed to be lower than the upper surfaces of the first capping patterns 138 and 139. For example, after the conductive material (e.g., polysilicon) that fills the second contact trench CT2 is formed, an etchback process on the conductive material may be performed. Accordingly, the buried contact BC that forms a plurality of isolated regions may be formed. As the etchback process is performed, a part of the upper part of the spacer structure 140 and/or a part of the upper part of the first capping patterns 138 and 139 may be removed.

In some embodiments, a plug hole CPh may be formed on the substrate 100 of the core/peri region CORE/PERI. The plug hole CPh may penetrate the second interlayer insulating film 239, the first interlayer insulating film 245, and the liner film 225 to expose a part of the substrate 100. Alternatively, unlike the shown example, the plug hole CPh may penetrate the second interlayer insulating film 239 and the gate capping pattern 238 to expose a part of the gate electrode 230.

In some embodiments, the plug hole CPh may be formed after the buried contact BC is formed.

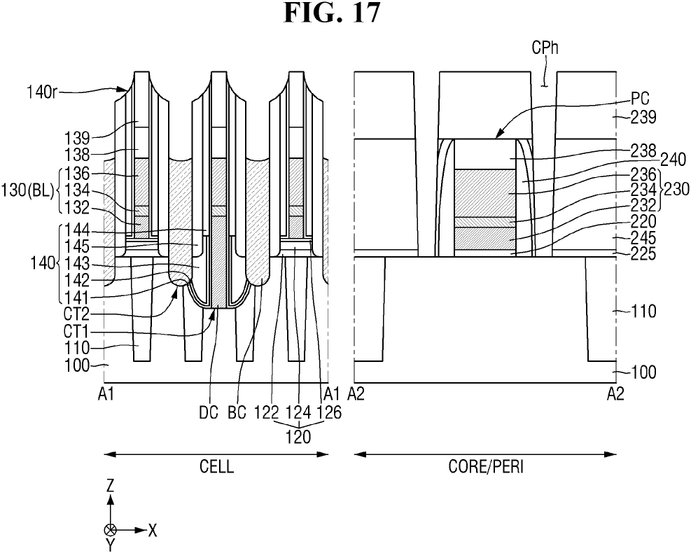

Referring to FIG. 17, a spacer recess 140r is formed in the upper part of the spacer structure 140.

For example, a recess process on the spacer structure 140 may be performed. The recess process may include, for example, but is not limited to, a wet etching process. As the spacer recess 140r is formed, the upper surface of the base spacer 141, and the upper surface of the first side spacer 144 and/or the second side spacer 145 may be exposed.

In some embodiments, the spacer recess 140r may be formed by the recess process performed only one time (i.e., a single recess process). In some embodiments, the spacer recess 140r may have an upward concave shape.

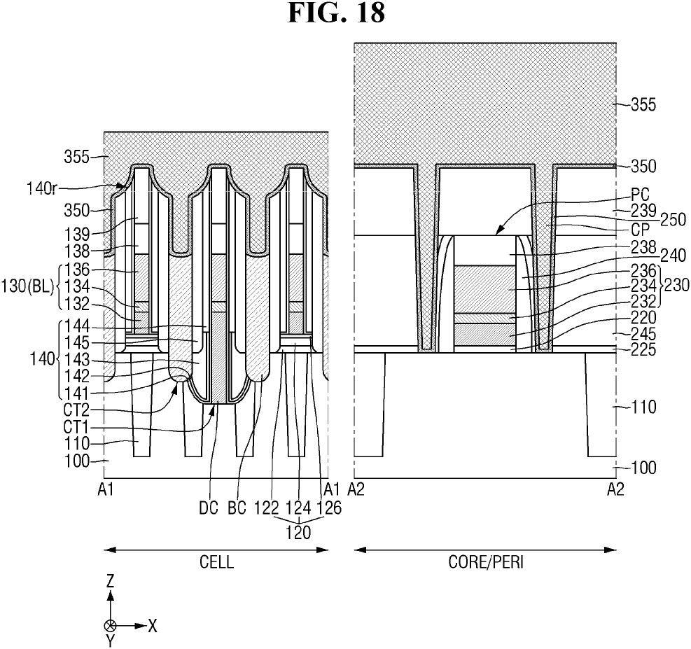

Referring to FIG. 18, a preliminary barrier conductive film 350 and a fourth conductive film 355 are sequentially formed on the buried contact BC.

In the cell region CELL, the preliminary barrier conductive film 350 may extend conformally along profiles of the upper surface of the buried contact BC, a part of the side surface of the spacer structure 140, the upper surface of the spacer structure 140, and the upper surface of the insulating fence 170. Further, the preliminary barrier conductive film 350 may extend conformally along the spacer recess 140r.

In the cell region CELL, the fourth conductive film 355 may be formed to fill the space between the plurality of spacer structures 140 and/or the space between the plurality of first capping patterns 138 and 139. Further, the upper surface of the fourth conductive film 355 may be formed to be higher than the uppermost surfaces of the first capping patterns 138 and 139.

In the core/peri region CORE/PERI, the preliminary barrier conductive film 350 may conformally extend along the profiles of the upper surface of the second interlayer insulating film 239 and the plug hole CPh.

In the core/peri region CORE/PERI, the fourth conductive film 355 may be formed to fill the plug hole CPh. Further, the upper surface of the fourth conductive film 355 may be formed to be higher than the upper surface of the second interlayer insulating film 239.

The fourth conductive film 355 may be formed, for example, by a vapor deposition process. In some embodiments, the fourth conductive film 355 may be formed by a chemical vapor deposition (CVD) process.

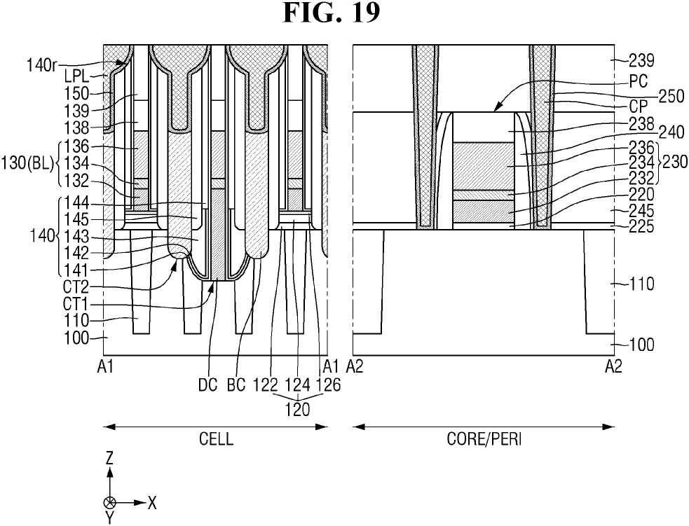

Referring to FIG. 19, the first barrier conductive film 150, the lower pad LPL, the second barrier conductive film 250, and the contact plug CP are formed.

For example, a flattening (e.g., planarization) process may be performed on the preliminary barrier conductive film 350 and the fourth conductive film 355. The flattening process may include, for example, but is not limited to, a chemical mechanical polishing (CMP) process.

As the flattening process is performed, the upper surfaces of the first capping patterns 138 and 139 may be exposed. Therefore, the first barrier conductive film 150 and the lower pad LPL may be formed inside the cell region CELL. As the flattening process is performed, the plurality of lower pads LPL (and the plurality of first barrier conductive films 150) may be separated from each other by the spacer structure 140 and the first capping patterns 138 and 139.

Further, as the flattening process is performed, the upper surface of the second interlayer insulating film 239 may be exposed. Accordingly, the second barrier conductive film 250 and the contact plug CP may be formed inside the core/peri region CORE/PERI.

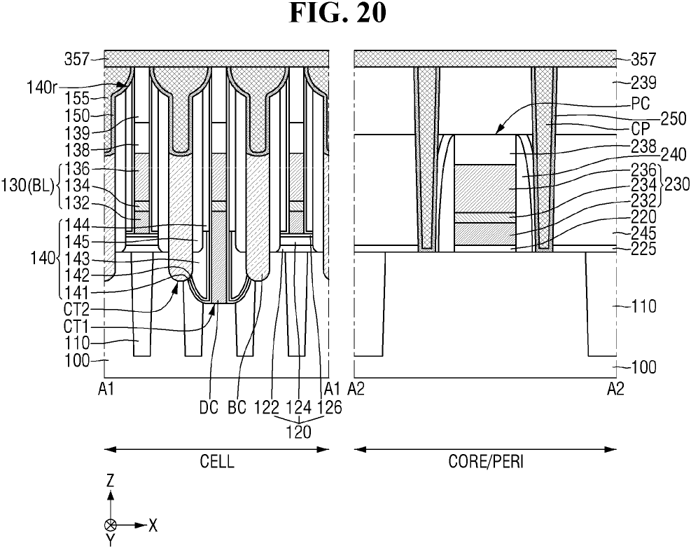

Referring to FIG. 20, a fifth conductive film 357 is formed on the first capping patterns 138 and 139, the lower pad LPL, the second interlayer insulating film 239, and the contact plug CP.

In the cell region CELL, the fifth conductive film 357 may be electrically connected to the lower pad LPL. In the core/peri region CORE/PERI, the fifth conductive film 357 may be electrically connected to the contact plug CP.

The fifth conductive film 357 may be formed, for example, by a vapor deposition step. In some embodiments, the fifth conductive film 357 may be formed by a physical vapor deposition (PVD) process.

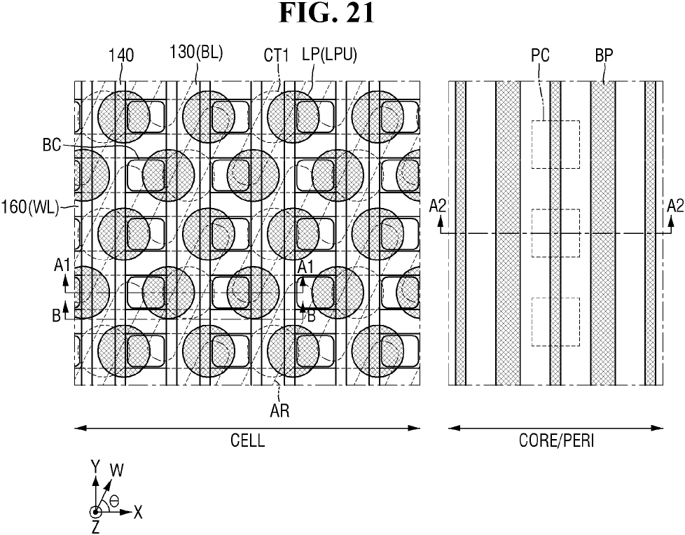

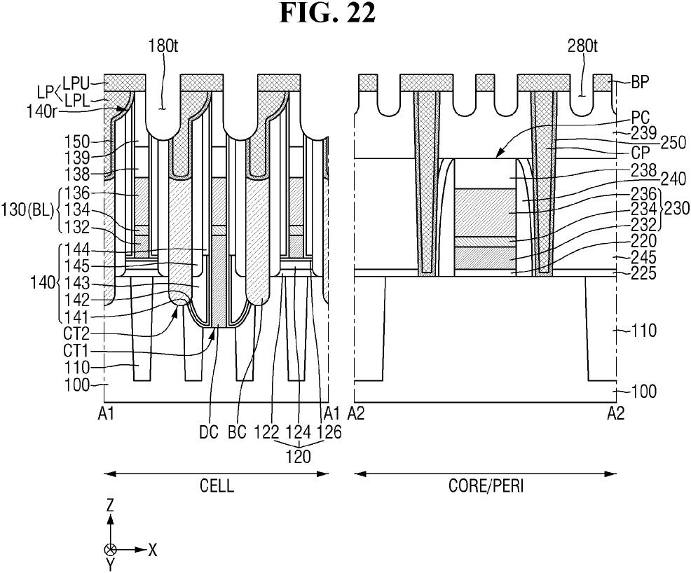

Referring to FIGS. 21 and 22, the landing pad LP and the wiring pattern BP are formed.

For example, a patterning process on the fifth conductive film 357 may be performed. As the patterning process is performed, a pad trench 180t that defines a plurality of landing pads LP may be formed inside the cell region CELL, and a wiring trench 280t that defines the plurality of wiring patterns BP may be formed inside the core/peri region CORE/PERI. A plurality of landing pads LP may be separated from each other by the pad trench 180t, and a plurality of wiring patterns BP may be separated from each other by the wiring trench 280t.

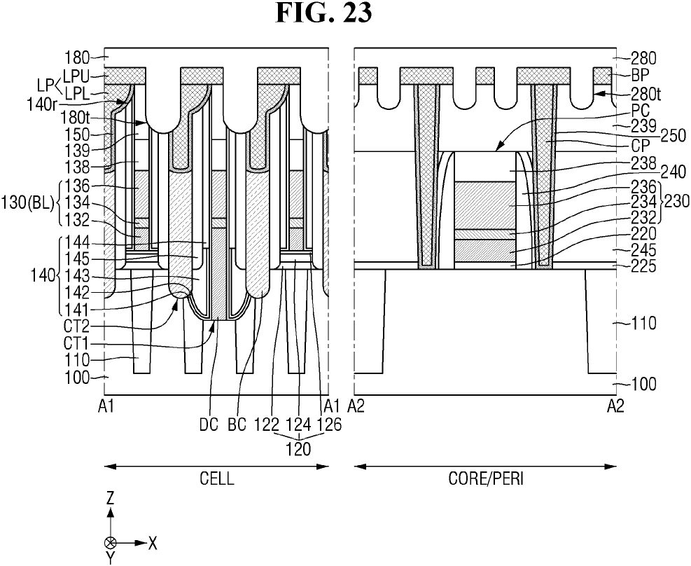

Referring to FIG. 23, the first separation insulating film 180 and the second separation insulating film 280 are formed.

For example, an insulating film that fills the pad trench 180t and the wiring trench 280t may be formed. The insulating film of the cell region CELL may form the first separated insulating film 180 by separating the plurality of landing pads LP from each other, and the insulating film of the core/peri region CORE/PERI may form the second separation insulating film 280 by separating the plurality of wiring patterns BP from each other.

Next, referring to FIGS. 2 to 7, the capacitor structure 190 is formed on the first separation insulating film 180.

For example, the first separation insulating film 180 may be patterned to expose at least a part of the upper surface of each landing pad LP. Subsequently, the lower electrode 192, the capacitor dielectric film 194, and the upper electrode 196 may be sequentially formed on the landing pad LP exposed by the first separation insulating film 180.

As the interval between adjacent landing pads LP gradually decreases, a poor connection such as an interconnection of adjacent landing pads LP or a disconnection of each landing pad may occur.

For example, as the interval between adjacent landing pads LP decreases, each landing pad LP may be formed too narrow, and a poor connection such as a disconnection of the landing pad LP may occur. However, in the semiconductor memory device according to some embodiments, the spacer structure 140 may impede/prevent the poor connection of the landing pad LP, by including the spacer recess 140r. Specifically, as described above, since the spacer recess 140r may be formed by removing a part of the upper part of the spacer structure 140, it is possible to inhibit/prevent the neck of the landing pad LP (e.g., neck LPb of FIG. 4A) from being formed too narrow, and may provide a large space for the head of the landing pad LP (e.g., head LPc of FIG. 4A).

Further, as the interval between adjacent landing pads LP decreases, a poor connection such as mutual interference or a connection between adjacent landing pads LP may occur. Such a poor connection tends to occur at deeper levels when the pad trench 180t for separating the landing pads LP from each other is formed deeper.

However, in the semiconductor memory device according to some embodiments, because the spacer recess 140r may be formed relatively shallow, the pad trench 180t may also be formed relatively shallow. Specifically, as described above, since the spacer recess 140r may be formed by a recess process performed only once, the height of the uppermost part of the spacer recess 140r may be formed to a level similar to the height of the uppermost surfaces of the first capping patterns 138 and 139. As a result, because the pad trench 180t may be formed relatively shallow (for example, with a depth of about 200 Å to about 400 Å), a poor connection between adjacent landing pads LP may be effectively inhibited/prevented.

Further, in the semiconductor memory device according to some embodiments, because the landing pad LP is provided with the lower pad LPL and the upper pad LPU formed separately, it is possible to more effectively inhibit/prevent poor connection of the landing pad LP. Specifically, as mentioned above, the plurality of lower pads LPL may be first separated from each other by a flattening process of exposing the upper surfaces of the first capping patterns 138 and 139, and the upper pads LPU may be formed separately on the lower pad LPL. Such a process can more effectively inhibit/prevent a poor connection such as mutual interference or a connection between adjacent landing pads LP, as compared with a process of patterning the lower pad LPL and the upper pad LPU at the same time (or simultaneously).

Accordingly, it is possible to provide a semiconductor memory device in which defects are improved and reliability is enhanced, and a method for fabricating the same.

While the present inventive concept has been particularly shown and described with reference to example embodiments thereof, it will be understood by those of ordinary skill in the art that various changes in form and details may be made therein without departing from the scope of the present inventive concept as defined by the following claims. It is therefore desired that the present embodiments be considered in all respects as illustrative and not restrictive, reference being made to the appended claims rather than the foregoing description to indicate the scope of the invention.

1. A semiconductor memory device comprising:
a substrate;
a first conductive line on the substrate;
a capping pattern that extends along an upper surface of the first conductive line;
a spacer structure that extends along a side surface of the first conductive line and a side surface of the capping pattern;
a buried contact electrically connected to the substrate, on a side surface of the spacer structure;
a barrier conductive film extending along the buried contact and the spacer structure; and
a landing pad electrically connected to the buried contact, on the barrier conductive film and the capping pattern,
wherein an upper part of the spacer structure includes a spacer recess that is lower than or equal to an uppermost surface of the capping pattern, and
wherein the barrier conductive film extends along the spacer recess and does not cover the uppermost surface of the capping pattern.

2. The semiconductor memory device of claim 1,
wherein the spacer structure includes a first side spacer and a second side spacer that are sequentially stacked on the side surface of the first conductive line and the side surface of the capping pattern, and include different materials from each other, and
wherein the barrier conductive film extends along the spacer recess and is in contact with an upper surface of the first side spacer and an upper surface of the second side spacer that are each lower than the uppermost surface of the capping pattern.

3. The semiconductor memory device of claim 2,
wherein the first side spacer includes silicon oxide, and
wherein the second side spacer includes silicon nitride.

4. The semiconductor memory device of claim 2, wherein the spacer structure further includes a base spacer that is between the first conductive line and the first side spacer and between the capping pattern and the first side spacer, and includes a material different from the first side spacer.

5. The semiconductor memory device of claim 4,
wherein the first side spacer includes silicon oxide, and
wherein each of the second side spacer and the base spacer includes silicon nitride.

6. The semiconductor memory device of claim 1, wherein the spacer recess has an upward concave shape.

7. The semiconductor memory device of claim 1, wherein the landing pad includes:
a lower pad on the side surface of the capping pattern and the side surface of the spacer structure; and
an upper pad that is in contact with an uppermost surface of the barrier conductive film and the uppermost surface of the capping pattern, on the lower pad.

8. The semiconductor memory device of claim 1, wherein the landing pad includes:
a tail on the buried contact;
a neck having a width narrower than the tail, on the tail; and
a head having a width greater than the neck, on the neck.

9. The semiconductor memory device of claim 8, wherein a part of the head is in the spacer recess.

10. The semiconductor memory device of claim 1, further comprising:
a direct contact that electrically connects an active region of the substrate and the first conductive line;
a second conductive line that extends in a direction intersecting the first conductive line, and crosses the active region between the direct contact and the buried contact; and
a capacitor structure electrically connected to the landing pad.

11. A semiconductor memory device comprising:
a substrate;
a first conductive line on the substrate;
a capping pattern that extends along an upper surface of the first conductive line;
a spacer structure that includes a first side spacer and a second side spacer that are stacked sequentially on a side surface of the first conductive line and a side surface of the capping pattern, the first side spacer and the second side spacer including different materials from each other;
a buried contact electrically connected to the substrate on a side surface of the spacer structure;
a first barrier conductive film extending along the buried contact and the spacer structure; and
a landing pad electrically connected to the buried contact, on the first barrier conductive film and the capping pattern,
wherein an upper part of the spacer structure includes a spacer recess that is lower than or equal to an uppermost surface of the capping pattern,
wherein the first barrier conductive film extends along the spacer recess and is in contact with an upper part of the first side spacer and an upper part of the second side spacer, and
wherein the landing pad includes a lower pad on the side surface of the capping pattern and the side surface of the spacer structure, and an upper pad that is in contact with an uppermost surface of the first barrier conductive film and the uppermost surface of the capping pattern, on the lower pad.

12. The semiconductor memory device of claim 11, wherein an uppermost surface of the lower pad, the uppermost surface of the first barrier conductive film, and the uppermost surface of the capping pattern are coplanar.

13. The semiconductor memory device of claim 11, wherein the lower pad is narrower than the upper pad.

14. The semiconductor memory device of claim 11, wherein the lower pad is thicker than the upper pad.

15. The semiconductor memory device of claim 11, wherein the lower pad and the upper pad include the same material as each other.

16. (canceled)

17. The semiconductor memory device of claim 11,
wherein the landing pad is in a cell region of the semiconductor memory device,
wherein a core/peripheral region of the semiconductor memory device is around the cell region, and
wherein the semiconductor memory device further comprises:
a peripheral circuit element on the substrate in the core/peripheral region;
a contact plug electrically connected to the substrate, on a side surface of the peripheral circuit element;
a second barrier conductive film extending along a lower surface and a side surface of the contact plug; and
a wiring pattern that is in contact with an uppermost surface of the second barrier conductive film and an uppermost surface of the contact plug.

18. The semiconductor memory device of claim 17,
wherein the first barrier conductive film and the second barrier conductive film are at the same level,
wherein the lower pad and the contact plug are at the same level, and
wherein the upper pad and the wiring pattern are at the same level.

19. (canceled)

20. A semiconductor memory device comprising:
a substrate including an active region;
a bit line extending in a first direction on the substrate;
a direct contact that electrically connects the active region and the bit line;
a first capping pattern that extends along an upper surface of the bit line;
a spacer structure that extends along a side surface of the bit line and a side surface of the first capping pattern;
a buried contact electrically connected to the active region, on a side surface of the spacer structure;
a barrier conductive film extending along the buried contact and the spacer structure;
a landing pad electrically connected to the buried contact, on the barrier conductive film and the first capping pattern;
a capacitor structure that is electrically connected to the landing pad, on the landing pad; and
a word line that extends in a second direction intersecting the first direction, and crosses the active region between the direct contact and the buried contact,
wherein an upper part of the spacer structure includes a curved region that is lower than or equal to an uppermost surface of the first capping pattern, and
wherein the barrier conductive film extends along the curved region of the spacer structure and does not cover the uppermost surface of the first capping pattern.

21. The semiconductor memory device of claim 20,
wherein the substrate includes a gate trench extending in the second direction, and
wherein the word line is inside the gate trench.

22. The semiconductor memory device of claim 21, further comprising:
a second capping pattern extending along an upper surface of the word line, inside the gate trench.

23-30. (canceled)
